(19) United States
(12) Patent Application Publication
(10) Pub. No.: US 2025/0323613 A1
(43) Pub. Date: Oct. 16, 2025

(54) FEED-FORWARD BASELINE WANDER COMPENSATION

(71) Applicant: QUALCOMM Incorporated, San Diego, CA (US)

(72) Inventors: Minghsien TSAI, Irvine, CA (US); Younwoong CHUNG, San Diego, CA (US); Yu SONG, San Diego, CA (US); Anjana Reddy KOMMAREDDI, San Diego, CA (US)

(21) Appl. No.: 18/633,695

(22) Filed: Apr. 12, 2024

(51) Int. Cl. H03F 3/45; H03F 1/08

(52) U.S. Cl. CPC H03F 3/45695; H03F 1/083; H03F 3/45475; H03F 2200/261

(57) ABSTRACT

An interface circuit configured in accordance with certain aspects of this disclosure has a high-pass filter and a low-pass filter. The high-pass filter may include a capacitor coupled between an input of the interface circuit and an output of the interface circuit and a resistor coupled between the output of the interface circuit and a voltage reference source. The capacitor and resistor may be configured to provide a low-pass filter that couples the reference voltage source to the output of the interface circuit. The interface circuit provides a feedforward loop that includes the reference voltage source and an amplifier. The amplifier has an input coupled to the input of the interface circuit and an output coupled to the reference voltage source.

### TECHNICAL FIELD

The present disclosure generally relates to input circuits in high-speed interfaces and, more particularly, to baseline voltage wander in capacitor-blocked input circuits.

### BACKGROUND

Electronic device technologies have seen explosive growth over the past several years. For example, growth of cellular and wireless communication technologies has been fueled by better communications, hardware, larger networks, and more reliable protocols. Wireless service providers are now able to offer their customers an ever-expanding array of features and services, and provide users with unprecedented levels of access to information, resources, and communications. To keep pace with these service enhancements, mobile electronic devices (e.g., cellular phones, tablets, laptops, etc.) have become more powerful and complex than ever. Wireless devices may include a high-speed bus interface for communication of signals between hardware components. For example, the high-speed bus interface may be implemented using a Peripheral Component Interconnect Express (PCIe) bus. High frequency signals being communicated using the bus interface may experience attenuation, interference and timing drift. There is an ongoing need to monitor the configuration and operation of receiving circuits when data links are subject to dynamic changes.

### SUMMARY

Certain aspects of the disclosure relate to systems, apparatus, methods and techniques for suppressing baseline wandering. Baseline wandering may occur in an input circuit in which direct current voltages in high-frequency signals are blocked using capacitors.

In various aspects of the disclosure, an interface circuit includes a high-pass filter and a feedforward loop. The high-pass filter includes a capacitor coupled between an input of the interface circuit and an output of the interface circuit, and a resistor coupled between the output of the interface circuit and a voltage reference source. The feedforward loop includes the reference voltage source and an amplifier that has an input coupled to the input of the interface circuit and an output coupled to the reference voltage source. The capacitor and resistor are configured to operate as a low-pass filter that couples the reference voltage source to the output of the interface circuit.

A differential interface circuit includes a differential amplifier configured to receive an input of the differential interface circuit and a high-pass filter. The high-pass filter includes a first capacitor coupled between a first complementary input of the interface circuit and a first complementary output of the interface circuit, and a resistor coupled between the first complementary output of the interface circuit and a first complementary output of the differential amplifier, a second capacitor coupled between a second complementary input of the interface circuit and a second complementary output of the interface circuit, and a resistor coupled between the a second complementary output of the interface circuit and a second complementary output of the differential amplifier. The first capacitor and the first resistor are configured to operate as a low-pass filter that couples the first complementary output of the differential amplifier to the first complementary output of the interface circuit. The second capacitor and the second resistor are configured to operate as a low-pass filter that couples the second complementary output of the differential amplifier to the second complementary output of the interface circuit.

In various aspects of the disclosure, a method for suppressing baseline wander includes filtering an input signal received by an interface circuit using a high-pass filter to obtain a filtered high-frequency signal, filtering the input signal using a low-pass filter to obtain a filtered low-frequency signal, adding the filtered low-frequency signal to a reference voltage using a summer, and combining the filtered high-frequency signal with an output of the summer to provide an output of the interface circuit.

In one aspect, the reference voltage source is configured to sum the voltage at an output of the amplifier with a reference voltage to provide an output of the reference voltage source. The feedforward loop can be configured to provide a unitary gain path from the input of the interface circuit to the output of the interface circuit for direct current signals. In one aspect, a signal transmitted through the feedforward loop may counteract changes to a baseline voltage level at the output of the interface circuit attributable to a signal transmitted through the high-pass filter. The input of the interface circuit may be configured to receive a high-frequency signal in excess of 100 MHz from a data communication link. The high-pass filter can provide a low-impedance path from the input of the interface circuit to the output of the interface circuit for high-frequency signals. In one aspect, the output of the interface circuit is coupled to an equalizer in a high-speed SERDES PHY circuit.

### BRIEF DESCRIPTION OF THE DRAWINGS

FIG. 1 illustrates an example of a system-on-a-chip (SOC) in accordance with certain aspects of the present disclosure.

FIG. 2 illustrates an example of a system that employs a multi-channel data communication link.

FIG. 3 illustrates an example of a circuit that uses a capacitor to change the common mode voltage of a high-speed signal.

FIG. 4 illustrates an example of a circuit that may be used to minimize the effect of baseline wander.

FIG. 5 illustrates an example of a system that uses digital processing to compensate for the effects of baseline wander.

FIG. 6 illustrates a first example of an input circuit that includes a feedforward path in accordance with certain aspects of this disclosure.

FIG. 7 is a second example of an input circuit that includes a feedforward path in accordance with certain aspects of this disclosure.

FIG. 8 is a flow diagram illustrating an example of a method for suppressing baseline wander in a high-speed serial interface according to certain aspects of this disclosure.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well-known structures and components are shown in block diagram form in order to avoid obscuring such concepts.

With reference now to the figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

The terms “computing device” and “mobile device” are used interchangeably herein to refer to any one or all of servers, personal computers, smartphones, cellular telephones, tablet computers, laptop computers, notebooks, ultrabooks, palm-top computers, personal data assistants (PDAs), wireless electronic mail receivers, multimedia Internet-enabled cellular telephones, Global Positioning System (GPS) receivers, wireless gaming controllers, and similar personal electronic devices which include a programmable processor. While the various aspects are particularly useful in mobile devices (e.g., smartphones, laptop computers, etc.), which have limited resources (e.g., processing power, battery, size, etc.), the aspects are generally useful in any computing device that may benefit from improved processor performance and reduced energy consumption.

The term “multicore processor” is used herein to refer to a single integrated circuit (IC) chip or chip package that contains two or more independent processing units or cores (e.g., CPU cores, etc.) configured to read and execute program instructions. The term “multiprocessor” is used herein to refer to a system or device that includes two or more processing units configured to read and execute program instructions.

The term “system on chip” (SoC) is used herein to refer to a single integrated circuit (IC) chip that contains multiple resources and/or processors integrated on a single substrate. A single SoC may contain circuitry for digital, analog, mixed-signal, and radio-frequency functions. A single SoC may also include any number of general purpose and/or specialized processors (digital signal processors (DSPs), modem processors, video processors, etc.), memory blocks (e.g., read only memory (ROM), random access memory (RAM), flash, etc.), and resources (e.g., timers, voltage regulators, oscillators, etc.), any or all of which may be included in one or more cores.

Memory technologies described herein may be suitable for storing instructions, programs, control signals, and/or data for use in or by a computer or other digital electronic device. Any references to terminology and/or technical details related to an individual type of memory, interface, standard, or memory technology are for illustrative purposes only, and not intended to limit the scope of the claims to a particular memory system or technology unless specifically recited in the claim language. Mobile computing device architectures have grown in complexity, and now commonly include multiple processor cores, SoCs, co-processors, functional modules including dedicated processors (e.g., communication modem chips, GPS receivers, etc.), complex memory systems, intricate electrical interconnections (e.g., buses and/or fabrics), and numerous other resources that execute complex and power intensive software applications (e.g., video streaming applications, etc.).

Certain aspects of the disclosure are applicable to input/output (I/O) circuits that provide an interface between core circuits and memory devices. Many mobile devices employ Synchronous Dynamic Random Access Memory (SDRAM), including Low-Power Double Data Rate (DDR) SDRAM, which may be referred to as DDR SDRAM, low-power DDR SDRAM, LPDDR SDRAM or, in some instances, LPDDRx where x describes the technology generation of the LPDDR SDRAM. Later generations of LPDDR SDRAM designed to operate at higher operating frequencies may employ lower voltage levels in the core of an SoC or memory device to mitigate for increased power associated with the higher operating frequencies.

Certain aspects of the disclosure are applicable to circuits that generate, transmit, receive, process and/or propagate differential signals. A differential signal pair comprises two signals that are phase-shifted from each other by 180°. The signals in the differential signal pair may be referred to as complementary signals. The differential signal pair is transmitted over wires, connectors, interconnects or other conductors using voltages of equal voltage magnitude and opposite polarity. A received signal that represents the difference between the differential signal pair can be generated at a receiving device. Common-mode noise affecting wires, connectors, interconnects or other conductors can be expected to induce a near-identical interference signal in the received differential signal pair, and the interference signal is typically cancelled at the receiver and does not affect the received signal.

Process technology employed to manufacture semiconductor devices, including IC devices is continually improving. Process technology includes the manufacturing methods used to make IC devices and defines transistor size, operating voltages and switching speeds. Features that are constituent elements of circuits in an IC device may be referred as technology nodes and/or process nodes. The terms technology node, process node, process technology may be used to characterize a specific semiconductor manufacturing process and corresponding design rules. Faster and more power-efficient technology nodes are being continuously developed through the use of smaller feature size to produce smaller transistors that enable the manufacture of higher-density ICs.

Certain aspects of this disclosure relate to circuits used in a high-speed serializer-deserializer (SERDES) physical layer (PHY) circuits. Certain circuits are described that can be deployed in the analog front-end (AFE) of a receiver. In one example, some aspects of the disclosure relate to decision-feedback equalizers that include a plurality of decision-feedback circuits in parallel with the data input circuit of a receiving device.

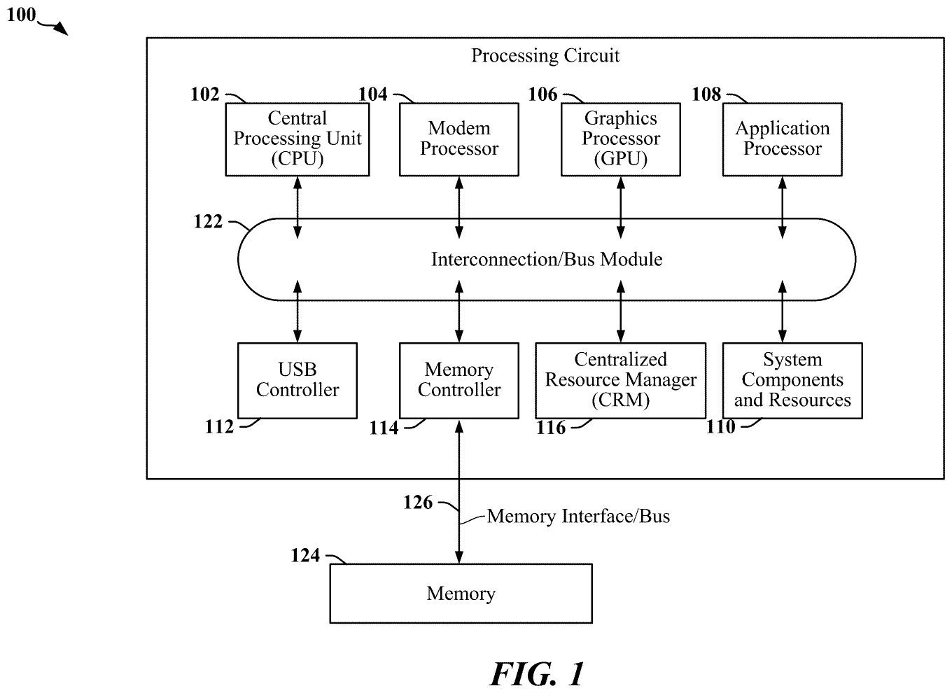

FIG. 1 illustrates example components and interconnections in a system-on-chip (SoC) 100 that may be suitable for implementing certain aspects of the present disclosure. The SoC 100 may include a number of heterogeneous processors, such as a central processing unit (CPU) 102, a modem processor 104, a graphics processor 106, and an application processor 108. Each processor 102, 104, 106, 108, may include one or more cores, and each processor/core may perform operations independent of the other processors/cores. The processors 102, 104, 106, 108 may be organized in close proximity to one another (e.g., on a single substrate, die, integrated chip, etc.) so that the processors may operate at a much higher frequency/clock rate than would be possible if the signals were to travel off-chip. The proximity of the cores may also allow for the sharing of on-chip memory and resources (e.g., voltage rails), as well as for more coordinated cooperation between cores.

The SoC 100 may include system components and resources 110 for managing sensor data, analog-to-digital conversions, and/or wireless data transmissions, and for performing other specialized operations (e.g., decoding high-definition video, video processing, etc.). System components and resources 110 may also include components such as voltage regulators, oscillators, phase-locked loops (PLLs), peripheral bridges, data controllers, system controllers, access ports, timers, and/or other similar components used to support the processors and software clients running on the computing device. The system components and resources 110 may also include circuitry for interfacing with peripheral devices, such as cameras, electronic displays, wireless communication devices, external memory chips, etc.

The SoC 100 may further include a Universal Serial Bus (USB) or other serial bus controller 112, one or more memory controllers 114, and a centralized resource manager (CRM) 116. The SoC 100 may also include an input/output module (not illustrated) for communicating with resources external to the SoC, each of which may be shared by two or more of the internal SoC components.

The processors 102, 104, 106, 108 may be interconnected to the USB controller 112, the memory controller 114, system components and resources 110, CRM 116, and/or other system components via an interconnection/bus module 122, which may include an array of reconfigurable logic gates and/or implement a bus architecture. Communications may also be provided by advanced interconnects, such as high-performance networks on chip (NoCs).

The interconnection/bus module 122 may include or provide a bus mastering system configured to grant SoC components (e.g., processors, peripherals, etc.) exclusive control of the bus (e.g., to transfer data in burst mode, block transfer mode, etc.) for a set duration, number of operations, number of bytes, etc. In some cases, the interconnection/bus module 122 may implement an arbitration scheme to prevent multiple master components from attempting to drive the bus simultaneously. The memory controller 114 may be a specialized hardware module configured to manage the flow of data to and from a memory 124 via a memory interface/bus 126.

The memory controller 114 may comprise one or more processors configured to perform read and write operations with the memory 124. Examples of processors include microprocessors, microcontrollers, digital signal processors (DSPs), field programmable gate arrays (FPGAs), programmable logic devices (PLDs), state machines, gated logic, discrete hardware circuits, and other suitable hardware configured to perform the various functionality described throughout this disclosure. In certain aspects, the memory 124 may be part of the SoC 100.

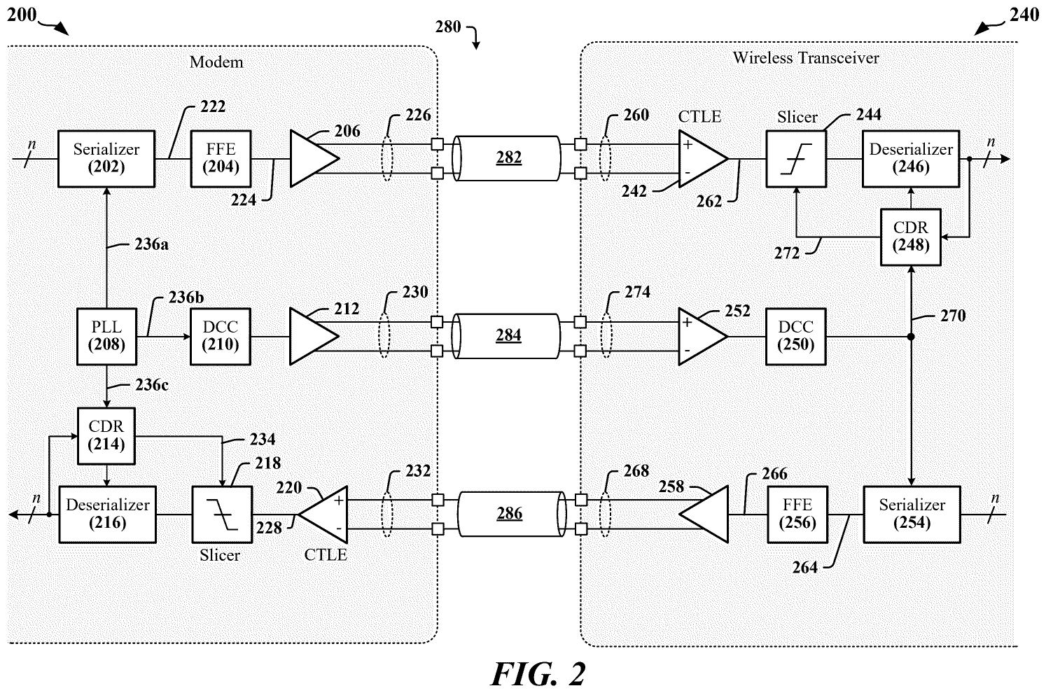

FIG. 2 illustrates an example of a system that employs a multi-channel data communication link 280 to couple a modem 200 with a wireless transceiver 240. The data communication link 280 employs a clock forwarding architecture in which a clock signal is transmitted to provide timing information at the receiver. The illustrated data communication link 280 includes data channels 282 and 286 and a clock channel 284 that provide a transmission medium through which signals propagate between devices. In the illustrated example, a modem 200 transmits data in a first signal over a first data channel 282 to a wireless transceiver 240 and receives data in a second signal transmitted over a second data channel 286. Data signals are transmitted over the data channels 282 and 286 in accordance with timing information provided by a bus clock signal 230 transmitted over the clock channel 284.

The modem 200 may include a serializer 202 configured to convert n-bit parallel data elements, bytes or words into a serial data stream for transmission in a transmit data signal 222 over the first data channel 282. The transmit data signal 222 may be preconditioned by a pre-equalizing circuit, such as the illustrated digital feed-forward equalizer (the FFE 204), in order to combat or compensate for signal distortions attributable to inter-symbol interference (ISI), reflection and other effects that can be expected to limit bandwidth in first data channel 282. The preconditioned transmit data signal 224 output by the FFE 204 is provided to a driver circuit 206 that is configured drive the first data channel 282.

The modem 200 may include a serializer 202 configured to convert n-bit parallel data elements, bytes or words into a serial data stream for transmission in a serialized data signal 222. The serialized data signal 222 may be preconditioned by a pre-equalizing circuit, such as the illustrated digital feed-forward equalizer (the FFE 204), in order to combat or compensate for signal distortions attributable to inter-symbol interference (ISI), reflection and other effects that can be expected to limit bandwidth in the first data channel 282. A preconditioned data signal 224 output by the FFE 204 is provided to a driver circuit 206 that is configured generate and transmit a differential transmit data signal 226 over the first data channel 282.

The wireless transceiver 240 can be configured to process a data signal 260 received over the first data channel 282. The data signal 260 may be provided to a differential receiver 242, which may include or cooperate with an equalizing circuit. In one example, continuous time linear equalization (CTLE) may be used to compensate for certain losses experienced in the first data channel 282. The first data channel 282 may be characterized in some respects as a low-pass filter. In the illustrated example, the differential receiver 242 outputs an equalized data signal 262 that is sampled by a slicer 244. The slicer 244 may be implemented using a D-flipflop or the like and may be configured to capture signaling state of the equalized data signal 262 under the control of edges in a sampling clock signal 272 generated by a clock and data recovery circuit (the CDR circuit 248). The output of the slicer 244 may be provided to a deserializer 246 that is clocked in accordance with one or more clock signals provided by the CDR circuit 248. The CDR circuit 248 may be configured to delay or phase shift a receiver clock signal 270 to ensure that edges in the sampling clock signal 272 are timed to optimize sampling reliability. Additional phases of the receiver clock signal 270 may be generated by the CDR circuit 248 or another circuit to obtain in-phase and quadrature (I/Q) versions of the clock signal to be used by the slicer 244 and/or the deserializer 246. A quadrature signal has phase that is shifted by 90° with respect to an in-phase signal.

In the illustrated wireless transceiver 240, the receiver clock signal 270 is derived from a received bus clock signal 274 over the clock channel 284. A differential receiver 252 coupled to the clock channel 284 may be configured to equalize the received bus clock signal 274, and a duty cycle correction circuit 250 may be used to adjust the duty cycle of the receiver clock signal 270. The receiver clock signal 270 is provided to a serializer 254 that is configured to convert n-bit parallel data elements, bytes or words into a serial data stream for transmission in a serialized data signal 264. The serialized data signal 264 may be preconditioned by a pre-equalizing circuit, such as the illustrated FFE 256, in order to combat or compensate for signal distortions attributable to ISI, reflection and other effects that can be expected to limit bandwidth in the second data channel 286. A preconditioned data signal 266 output by the FFE 256 is provided to a driver circuit 258 that is configured generate and transmit a differential transmit data signal 268 over the second data channel 286.

The illustrated modem 200 can be configured to process a data signal 232 received over the second data channel 286. The data signal 232 may be provided to a differential receiver 220, which may include or cooperate with an equalizing circuit. In one example, CTLE may be used to compensate for certain losses experienced in the second data channel 286. The second data channel 286 may be characterized in some respects as a low-pass filter. In the illustrated example, the differential receiver 220 outputs an equalized data signal 228 that is sampled by a slicer 218. The slicer 218 may be implemented using a D-flipflop or the like and may be configured to capture signaling state of the equalized data signal 228 under the control of edges in a sampling clock signal 234 generated by a CDR circuit 214. The output of the slicer 218 may be provided to a deserializer 216 that is clocked in accordance with one or more clock signals provided by the CDR circuit 214. The CDR circuit 214 may be configured to delay or phase shift a transmitter clock signal to ensure that edges in the sampling clock signal 234 are timed to optimize sampling reliability.

A clock generation circuit, including the illustrated phase locked loop 208, may generate multiple clock signals 236a, 236b, 236c used by the modem 200. One or more of the clock signals 236a, 236b, 236c may be a divided version of a base clock signal generated by the PLL 208. One or more of the clock signals 236a, 236b, 236c may be phase shifted with respect to the base clock signal. In one example, the serializer 202 may produce the serialized data signal 222 using timing provided by a first clock signal 236a. In another example, the bus clock signal 230 transmitted over the clock channel 284 may be derived from a second clock signal 236b. In some instances, a duty cycle correction circuit 210 may be used to adjust the duty cycle of the second clock signal 236b and to provide an input to a driver circuit 212 that is configured drive the clock channel 284. In another example, the CDR circuit 248 may generate the sampling clock signal 234 from a third clock signal 236c.

In high-speed SERDES interfaces, data throughput of a serial data link may be limited by the characteristics of the channel used to carry data signals. Impedance mismatches, parasitic electromagnetic coupling and other factors can cause signal distortion. In many implementations, equalization circuits and capabilities are included in I/O circuits to compensate for signal distortions attributable to inter-symbol interference (ISI) and other effects that can combine to limit bandwidth in a channel. ISI can result when a first-received symbol interferes with subsequently received symbols due to reflections, frequency-dependent delays and other imperfections in the channel. A symbol may refer to signaling state within a unit interval (UI), or symbol interval, in which data is modulated or encoded in the waveform of a transmitted signal. In some instances, a DFE may be implemented in the receiver. The DFE is a nonlinear equalizer that can be configured to flatten channel response and limit signal distortion without introducing noise or crosstalk that can occur with equalizers that operate using amplification of received signals.

Signals received over multiwire high-speed interface may be subject to variations in common mode voltage. In one example, an identical direct current (DC) offset from system ground carried by two wires may be referred to as a common-mode voltage. The common-mode voltage may be measured at the input terminals of a receiving device. An identical signal carried in-phase by each wire of the pair may be referred to as a common-mode signal. Common-mode noise affecting wires, connectors, interconnects or other conductors can be expected to induce a near-identical interference signal in a wire pair that carries a differential signal. The interference signal is typically cancelled by subtraction at the receiver and does not affect the received differential signal.

In some interfaces, capacitors may be used to block common mode voltages and thereby acquire a known baseline voltage level at the receiver. In some systems, the baseline voltage level is nominally an average of the signal level at the receiver. For example, the baseline voltage level for a typical binary-encoded signal that switches between nominal zero and V voltage levels may be expected to at or near the V/2 voltage level. However, a long sequence of consecutive bit transmission intervals that have the same level can cause the baseline voltage level to vary. This variance due to characteristics of a signal is one example of baseline wander.

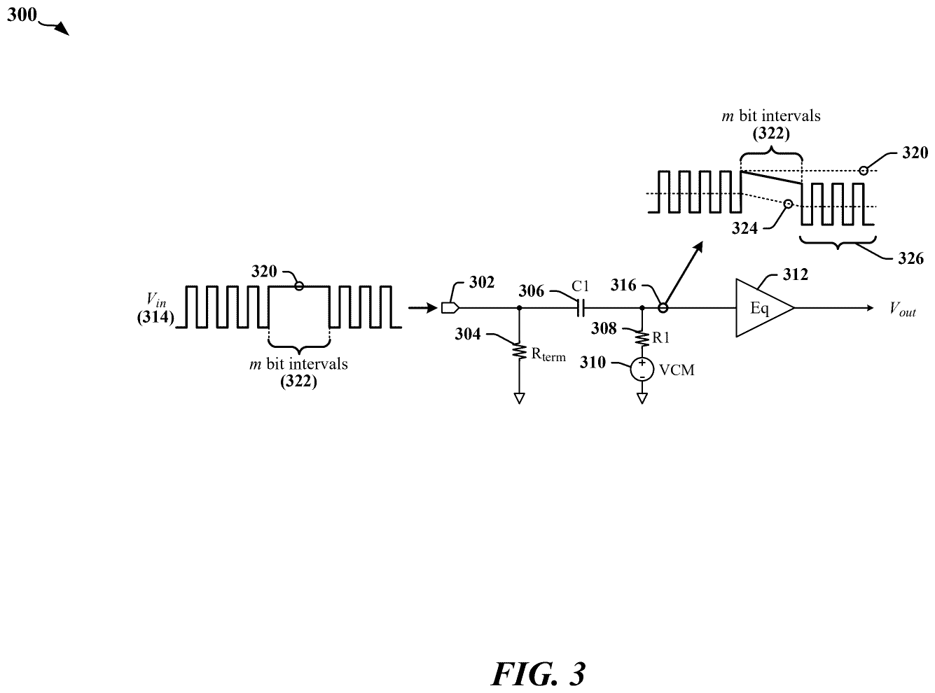

FIG. 3 illustrates an example of a circuit 300 that uses a capacitor 306 to change the common mode voltage of a high-speed signal 314. In the illustrated example, the high-speed signal 314 is received at an input 302 that is terminated using a resistor 304 that provides a 50 ohm (50Ω) resistance. The capacitor 306 couples the input 302 to a receiver circuit 312 that includes an equalizer. The capacitor 306 blocks direct current (DC) components of the high-speed signal 314 and the baseline voltage at an input 316 of the receiver circuit 312 is determined by a voltage source (the VCM source 310). The VCM source 310 is coupled to the input 316 of the receiver circuit 312 through a resistor 308. The capacitor 306 and resistor 308 implement a high-pass filter that has the transfer function:

$$\frac{{V}_{out}}{{V}_{i n}} = \frac{{SR}_{1} {C}_{1}}{1 + {SR}_{1} {C}_{1}} .$$

The baseline voltage at the input 316 of the receiver circuit 312 is subject to baseline wander. In the illustrated example, high-speed signal 314 is at a constant high signaling state 320 for multiple transmission intervals 322. The voltage at the input 316 of the receiver circuit 312 can be expected to decay from the voltage level of the high signaling state 320 during the multiple transmission intervals 322. The decayed voltage at the input 302 to a receiver circuit 312 causes a shift in baseline voltage level 324. The first negative edge in the high-speed signal 314 passes through the capacitor 306 and establishes a new low voltage signaling state at the input 316 of the receiver circuit 312, for a duration of time 326. The high-speed signal 314 begins to toggle about the shifted baseline voltage level 324. This shift or wandering of the baseline voltage to 324 at the input 316 of the receiver circuit 312 can cause link errors due to unreliable data capture and decoding. Rate of decay of the voltage of the signal at the input 316 of the receiver circuit 312 is determined by the capacitance (C1) of the capacitor 306 and the resistance (R1) of the resistor 308.

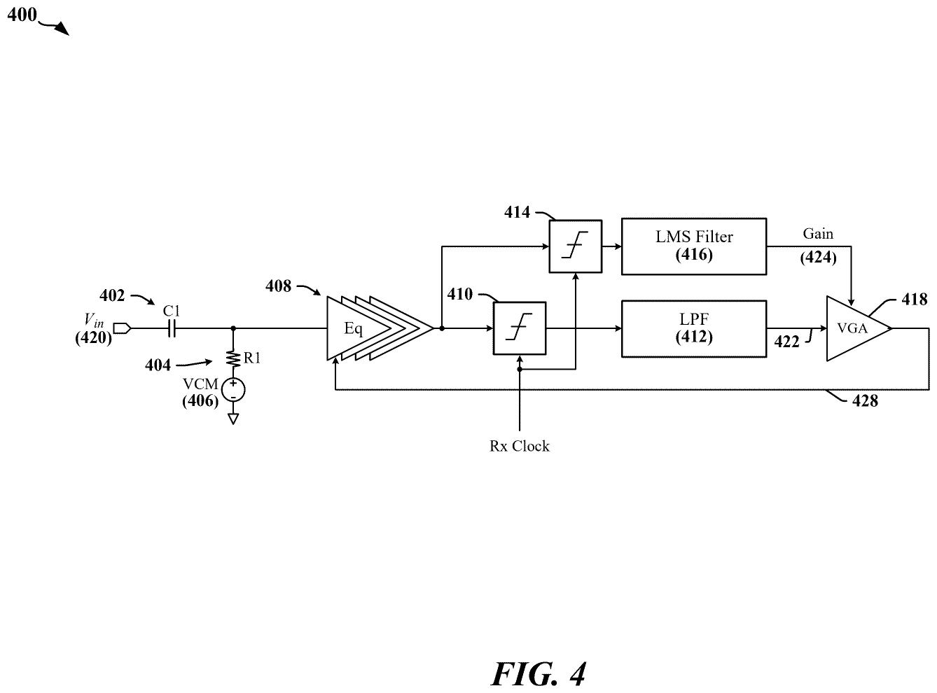

FIG. 4 illustrates an example of a circuit 400 that may be used to minimize the effect of baseline wander. In the illustrated example, the capacitance (C1) of the capacitor 402 that blocks the DC components of the high-speed signal 420 and the resistance (R1) of the resistor 404 that couples the voltage source (the VCM 406) to the input of the equalizing receiver circuits 408 are increased to minimize baseline wander. The increased resistance and capacitance increases the area of semiconductor die occupied by the circuit 400 and can affect the performance of equalization circuits. In the illustrated example, a compensation loop is provided using a feedback signal 428 to the equalizing receiver circuits 408. The feedback signal 428 is generated by a variable gain amplifier circuit (the VGA 418). A data sampler 410 captures data samples from the output of the equalizing receiver circuits 408. The output of the data sampler 410 is provided to a low-pass filter (the LPF 412). The VGA 418 responds to an output 422 of the LPF 412 to generate the feedback signal 428. The gain of the VGA 418 is controlled through an error processing path. An error sampler 414 captures data samples from the output of the equalizing receiver circuits 408. The output of the error sampler 414 is provided to a least means squares filter (the LMS filter 416) that generates a gain signal 424 to control the VGA 418. The operation of the compensation loop provided in the circuit 400 can vary due to manufacturing process variances, which may increase circuit complexity to compensate the control loop.

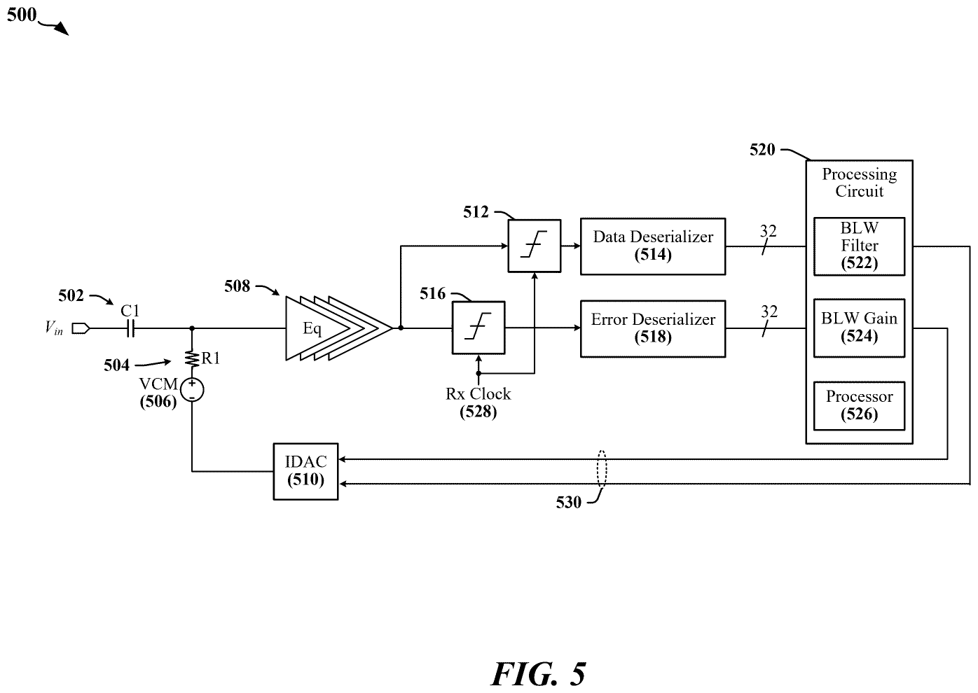

FIG. 5 illustrates an example of a system 500 that uses digital processing to compensate for the effects of baseline wander. In this example, variances and drift may be corrected at a processing circuit 520. In the illustrated example, baseline wander introduced by the capacitor 502 the resistor 504 may be corrected using a voltage source (the VCM 506) that provides a variable output voltage and that is controlled by a compensation loop. In the illustrated example, the compensation loop includes the processing circuit 520, which provides feedback 530 to the VCM 506. The processing circuit 520 may include one or more processors 526, controllers and/or finite state machines. In one example, the processing circuit 520 includes a general-purpose processor, a DSP or both.

A data sampler 512 captures data samples from the output of the equalizing receiver circuits 508. In the illustrated example, the output of the data sampler 512 is provided to a first deserializer 514 that generates 32-bit representations of data samples captured by the data sampler 512. An error sampler 516 captures data samples from the output of the equalizing receiver circuits 508, which are provided to a second deserializer 518 that generates 32-bit representations of data samples captured by the error sampler 516. In some implementations, the data sampler 512 and the error sampler 516 are configured to captures data samples using different phases or versions of a receiver clock signal 528. The processing circuit 520 may be configured with one or more digital filters and/or signal processing functions. In the illustrated example, the feedback 530 may include signals produced by a baseline wander filter 522 and a baseline wander gain control module 524. These signals may include multibit digital signals. In the illustrated example, the feedback signals may control the operation of a current digital-to-analog converter (the IDAC 510). In one implementation, the current output by the IDAC 510 may be determined by the output of baseline wander filter 522 and a gain signal produced by the baseline wander gain control module 524. The current output by the IDAC 510 is used to control the voltage output of the VCM 506.

A high-resolution baseline wander filter 522 is typically required to support the clock frequencies used for transmitting data over the communication link. The latency introduced by the deserializers 514, 518 can cause a deterioration of performance of the baseline wander filter 522. Increased power consumption and area of semiconductor die are generally required to improve filter accuracy and to reduce latency.

Certain aspects of this disclosure relate to circuits that can compensate for baseline wander without using a baseline wander compensation loop. The circuits can operate without a digital filter and feedback loop latency can be eliminated. No digital control of a baseline wander feedback gain is required. In one aspect, baseline wander compensation is accomplished through a feedforward path.

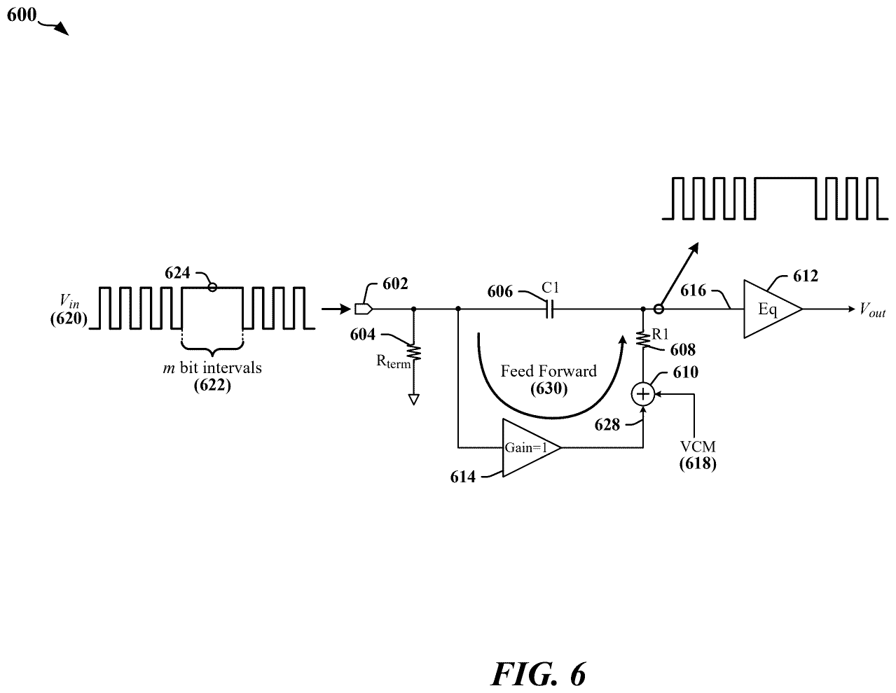

FIG. 6 illustrates a first example of an input circuit 600 that includes a feedforward path 630 in accordance with certain aspects of this disclosure. The feedforward path 630 can compensate for baseline wander. In the illustrated example, a high-speed signal 620 is received at an input 602 of the input circuit 600. In the illustrated example, the input 602 is coupled to a termination resistor 604. In some implementations, the termination resistor 604 provides a resistance of 50Ω. A capacitor 606 couples the input 602 to a receiver circuit 612. The receiver circuit 612 may include an equalizer. The capacitor 606 blocks direct current (DC) components of the high-speed signal 620.

The capacitor 606 and resistor 608 implement a high-pass filter between the input 602 of the input circuit 600 and the input 616 of the receiver circuit 612. The high-pass filter has the transfer function:

$$\frac{{V}_{out}}{{V}_{i n}} = \frac{{SR}_{1} {C}_{1}}{1 + S {R}_{1} {C}_{1}} .$$

The baseline voltage level at the input 616 of the receiver circuit 612 is determined by a combination of a reference voltage source 610 and a voltage level provided through the feedforward path 630. In the illustrated example, the feedforward path 630 includes an amplifier 614 that has unitary gain. The amplifier 614 may be configured to forward the DC level of the high-speed signal 620 to a first input 628 of the reference voltage source 610. In the illustrated example, the reference voltage source 610 receives a fixed common mode voltage level (VCM 618) at a second input. In one example, the reference voltage source 610 includes a summer that causes the reference voltage source 610 to generate an output that is the sum of its inputs. The output of the reference voltage source 610 is coupled to the input 616 of the receiver circuit 612 through the resistor 608.

The capacitor 606 and resistor 608 implement a low-pass filter between the output of the reference voltage source 610 and the input 616 of the receiver circuit 612. The low-pass filter has the transfer function:

$$\frac{{V}_{out}}{{V}_{i n}} = \frac{1}{1 + S {R}_{1} {C}_{1}} .$$

The combined transfer function for the input circuit 600 includes the transfer functions for the high-pass and the filter low-pass filter and may be stated as:

$$\frac{{V}_{out}}{{V}_{i n}} = \frac{{SR}_{1} {C}_{1}}{1 + {SR}_{1} {C}_{1}} + \frac{1}{1 + {SR}_{1} {C}_{1}} = \frac{1 + {SR}_{1} {C}_{1}}{1 + {SR}_{1} {C}_{1}} = 1 .$$

In the example in which the high-speed signal 620 is at a constant high signaling state 624 for multiple bit transmission intervals 622, the voltage at the input 616 of the receiver circuit 612 that is attributable to transmission through the high-pass filter can be expected to decay from the voltage level 624 of the high signaling state during the multiple bit transmission intervals 622. The voltage at the input 616 of the receiver circuit 612 that is attributable to transmission through the low-pass filter can be expected to increase during the multiple bit transmission intervals 622. As shown by the combined transfer function for the input circuit 600, the decay in voltage associated with the high-pass filter is cancelled by the increase in voltage associated with the low-pass filter in a nominal case.

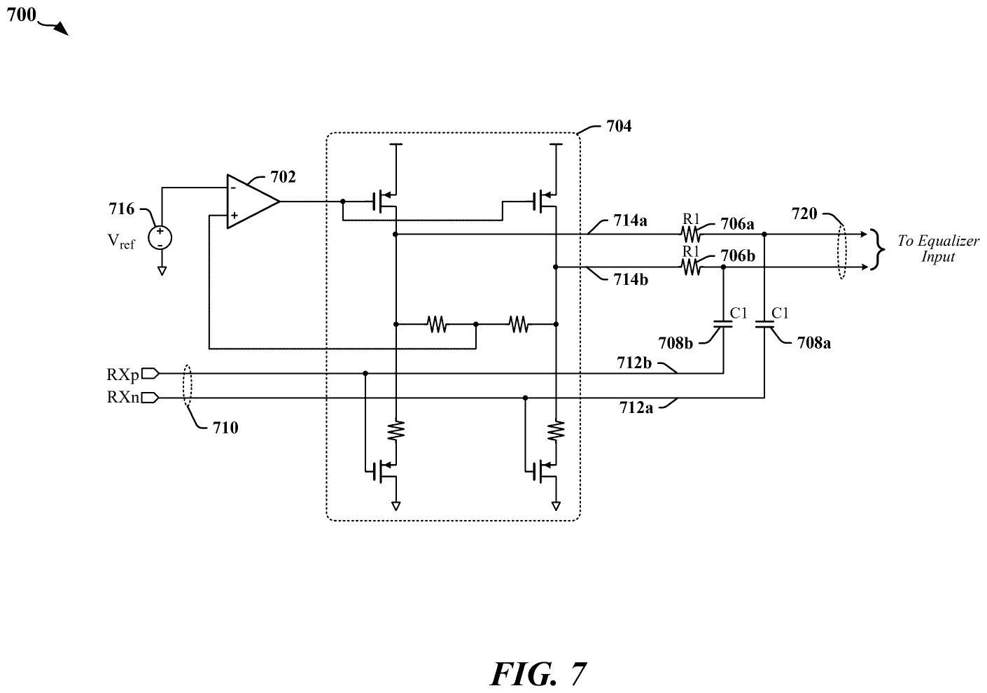

FIG. 7 is a second example of an input circuit 700 that includes a feedforward path in accordance with certain aspects of this disclosure. The input circuit 700 implements the feedforward path illustrated in FIG. 6. A high-pass filtered version 720 of a differential input signal 710 is provided to the input of a receiver or equalizer circuit (not shown). The differential input signal 710 includes complementary input signals 712a and 712b. A first complementary input signal 712a is provided to a first high-pass filter that comprises a first resistor 706a and a first capacitor 708a. A second complementary input signal 712b is provided to a second high-pass filter that that comprises a second resistor 706b and a second capacitor 708b. The resistors 706a, 706b and capacitors 708a, 708b operate as low-pass filters with respect to the complementary outputs 714a and 714b of an amplifier 704. The gain of the amplifier 704 is controlled by a comparator 702 based on the input DC voltage level baseline voltage and a reference voltage source 716 that controls the desired baseline voltage level. The differential output of the amplifier 704 is coupled to the input of the receiver or equalizer circuit. In the illustrated example, a first complementary output 714a of the amplifier 704 is provided to the first resistor 706a and a second complementary output 714b of the amplifier 704 is provided to the second resistor 706b. The first resistor 706a and the first capacitor 708a operate as a first low-pass filter in the DC path, being inserted between the amplifier 704 and the receiver or equalizer circuit. The second resistor 706b and the second capacitor 708b operate as a second low-pass filter inserted between the amplifier 704 and the receiver or equalizer circuit. In some implementations, the low-pass filter and the high-pass filter share one or more capacitors and one or more resistors.

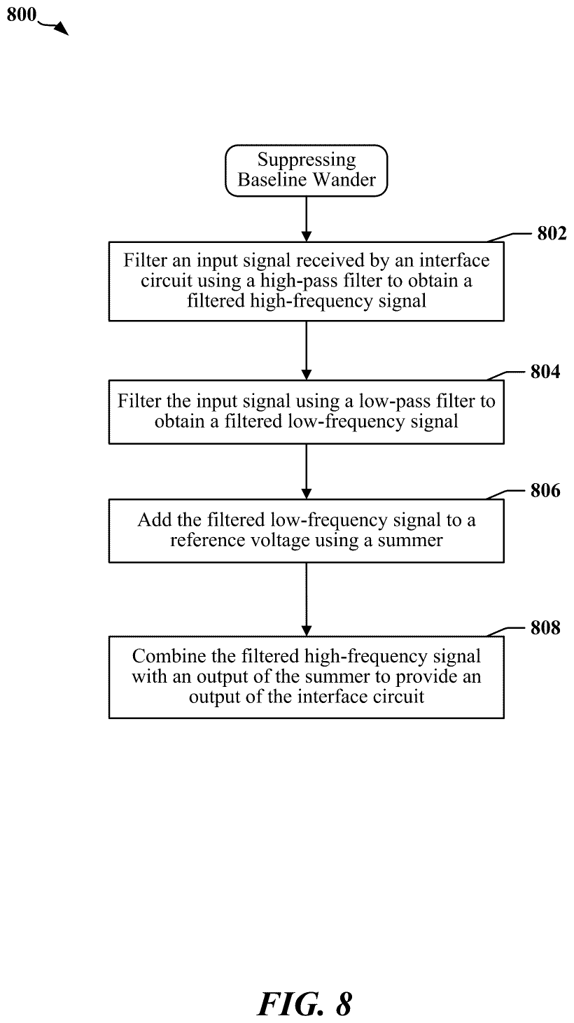

FIG. 8 is a flow diagram 800 illustrating an example of a method for suppressing baseline wander in a high-speed serial interface. The method may be performed using the input circuit 600 illustrated in FIG. 6 or the input circuit 700 illustrated in FIG. 7.

At block 802 of the flow diagram 800, an input signal received by an interface circuit may be filtered using a high-pass filter to obtain a filtered high-frequency signal. At block 804 the input signal may be concurrently filtered using a low-pass filter to obtain a filtered low-frequency signal. At block 806 the filtered low-frequency signal may be added to a reference voltage using a summer. At block 808, the filtered high-frequency signal may be combined with an output of the summer to provide an output of the interface circuit.

In some examples, combining the filtered high-frequency signal with an output of the summer counteracts changes to a baseline voltage level at the output of the interface circuit attributable to a signal transmitted through the high-pass filter.

In some implementations, the reference voltage is configured to define a baseline voltage level at the output of the interface circuit. In some examples, the input signal has frequency in excess of 100 MHz. The high-pass filter may be configured to provide a low-impedance path for the input signal.

An interface circuit configured in accordance with certain aspects of this disclosure has a high-pass filter and a low-pass filter. The high-pass filter may include a capacitor coupled between an input of the interface circuit and an output of the interface circuit and a resistor coupled between the output of the interface circuit and a voltage reference source. The capacitor and resistor may be configured to provide a low-pass filter that couples the reference voltage source to the output of the interface circuit. The interface circuit provides a feedforward loop that includes the reference voltage source and an amplifier. The amplifier has an input coupled to the input of the interface circuit and an output coupled to the reference voltage source.

In some implementations, the reference voltage source is configured to sum the voltage at an output of the amplifier with a reference voltage to provide an output of the reference voltage source. A signal transmitted through the feedforward loop may counteract changes to a baseline voltage level at the output of the interface circuit attributable to a signal transmitted through the high-pass filter. The input of the interface circuit may be configured to receive a high-frequency signal in excess of 100 MHz from a data communication link. The high-pass filter can provide a low-impedance path from the input of the interface circuit to the output of the interface circuit for high-frequency signals. The feedforward loop can be configured to provide a unitary gain path from the input of the interface circuit to the output of the interface circuit for direct current signals. In some implementations, the output of the interface circuit is coupled to an equalizer in a high-speed SERDES PHY circuit.

A differential interface circuit may be implemented using a differential amplifier configured to receive an input of the differential interface circuit and a high-pass filter. The high-pass filter may include a first capacitor coupled between a first complementary input of the interface circuit and a first complementary output of the interface circuit, and a resistor coupled between the first complementary output of the interface circuit and a first complementary output of the differential amplifier, a second capacitor coupled between a second complementary input of the interface circuit and a second complementary output of the interface circuit, and a resistor coupled between the a second complementary output of the interface circuit and a second complementary output of the differential amplifier. The first capacitor and the first resistor may be configured to operate as a low-pass filter that couples the first complementary output of the differential amplifier to the first complementary output of the interface circuit. The second capacitor and the second resistor may be configured to operate as a low-pass filter that couples the second complementary output of the differential amplifier to the second complementary output of the interface circuit.

In some implementations, the differential amplifier is configured to sum an output voltage of the amplifier with a reference voltage to provide an output of the differential amplifier. A signal provided through the low-pass filter may counteract changes to a baseline voltage level at the output of the interface circuit attributable to a signal transmitted through the high-pass filter. The input of the differential interface circuit may be configured to receive a high-frequency signal in excess of 100 MHz from a data communication link. The high-pass filter may provide a low-impedance path from the input of the differential interface circuit to the output of the differential interface circuit for high-frequency signals. The differential amplifier provides a unitary gain path from the input of the interface circuit to the output of the interface circuit for direct current signals. The output of the differential interface circuit may be coupled to an equalizer in a high-speed SERDES PHY circuit.

The operational steps described in any of the exemplary aspects herein are described to provide a subset of examples of possible implementations. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flow diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components with similar numbering.

In one example, an apparatus may include means for filtering an input signal received by an interface circuit. The means for filtering an input signal may include a high-pass filter and a low-pass filter. The high-pass filter may be used to obtain a filtered high-frequency signal. The low-pass filter may be used to obtain a filtered low-frequency signal. The apparatus may include means for adding the filtered low-frequency signal to a reference voltage using a summer, and apparatus may include means for combining the filtered high-frequency signal with an output of the summer to provide an output of the interface circuit.

Some implementation examples are described in the following numbered clauses:
1. An interface circuit, comprising: a high-pass filter that includes: a capacitor coupled between an input of the interface circuit and an output of the interface circuit, and a resistor coupled between the output of the interface circuit and a voltage reference source; and a feedforward loop comprising the reference voltage source and an amplifier that has an input coupled to the input of the interface circuit and an output coupled to the reference voltage source, wherein the capacitor and resistor are configured to operate as a low-pass filter that couples the reference voltage source to the output of the interface circuit.
2. The interface circuit as described in clause 1, wherein the reference voltage source is configured to sum the voltage at an output of the amplifier with a reference voltage to provide an output of the reference voltage source.
3. The interface circuit as described in clause 1 or clause 2, wherein a signal transmitted through the feedforward loop counteracts changes to a baseline voltage level at the output of the interface circuit attributable to a signal transmitted through the high-pass filter.
4. The interface circuit as described in any of clauses 1-3, wherein the input of the interface circuit is configured to receive a high-frequency signal in excess of 100 MHz from a data communication link.
5. The interface circuit as described in any of clauses 1-4, wherein the high-pass filter provides a low-impedance path from the input of the interface circuit to the output of the interface circuit for high-frequency signals.
6. The interface circuit as described in any of clauses 1-5, wherein the feedforward loop provides a unitary gain path from the input of the interface circuit to the output of the interface circuit for direct current signals.
7. The interface circuit as described in any of clauses 1-6, wherein the output of the interface circuit is coupled to an equalizer in a high-speed serializer-deserializer (SERDES) physical layer circuit.
8. A differential interface circuit, comprising: a differential amplifier configured to receive an input of the differential interface circuit; and a high-pass filter that includes: a first capacitor coupled between a first complementary input of the interface circuit and a first complementary output of the interface circuit, and a resistor coupled between the first complementary output of the interface circuit and a first complementary output of the differential amplifier, wherein the first capacitor and the first resistor are configured to operate as a low-pass filter that couples the first complementary output of the differential amplifier to the first complementary output of the interface circuit; a second capacitor coupled between a second complementary input of the interface circuit and a second complementary output of the interface circuit, and a resistor coupled between the a second complementary output of the interface circuit and a second complementary output of the differential amplifier, wherein the second capacitor and the second resistor are configured to operate as a low-pass filter that couples the second complementary output of the differential amplifier to the second complementary output of the interface circuit. a low-pass filter that couples the differential amplifier to an output of the differential interface circuit, the low-pass filter including the first capacitor, the first resistor and the second capacitor and the second resistor.
9. The differential interface circuit as described in clause 8, wherein the differential amplifier is configured to sum an output voltage of the amplifier with a reference voltage to provide an output of the differential amplifier.
10. The differential interface circuit as described in clause 8 or clause 9, wherein a signal provided through the low-pass filter counteracts changes to a baseline voltage level at the output of the interface circuit attributable to a signal transmitted through the high-pass filter.
11. The differential interface circuit as described in any of clauses 8-10, wherein the input of the differential interface circuit is configured to receive a high-frequency signal in excess of 100 MHz from a data communication link.
12. The differential interface circuit as described in any of clauses 8-11, wherein the high-pass filter provides a low-impedance path from the input of the differential interface circuit to the output of the differential interface circuit for high-frequency signals.
13. The differential interface circuit as described in any of clauses 8-12, wherein the differential amplifier provides a unitary gain path from the input of the interface circuit to the output of the interface circuit for direct current signals.
14. The differential interface circuit as described in any of clauses 8-13, wherein the output of the differential interface circuit is coupled to an equalizer in a high-speed serializer-deserializer (SERDES) physical layer circuit.
15. A method for suppressing baseline wander, comprising: filtering an input signal received by an interface circuit using a high-pass filter to obtain a filtered high-frequency signal; filtering the input signal using a low-pass filter to obtain a filtered low-frequency signal; adding the filtered low-frequency signal to a reference voltage using a summer; and combining the filtered high-frequency signal with an output of the summer to provide an output of the interface circuit.
16. The method as described in clause 15, wherein combining the filtered high-frequency signal with an output of the summer counteracts changes to a baseline voltage level at the output of the interface circuit attributable to a signal transmitted through the high-pass filter.
17. The method as described in clause 15 or clause 16, wherein the reference voltage is configured to define a baseline voltage level at the output of the interface circuit.
18. The method as described in any of clauses 15-17, wherein the input signal has frequency in excess of 100 MHz.
19. The method as described in any of clauses 15-18, wherein the high-pass filter provides a low-impedance path for the input signal.
20. The method as described in any of clauses 15-19, wherein the low-pass filter and the high-pass filter share one or more capacitors and one or more resistors.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The present disclosure is provided to enable any person skilled in the art to make or use aspects of the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and novel features disclosed herein.

What is claimed is:

1. An interface circuit, comprising:
a high-pass filter that includes:
a capacitor coupled between an input of the interface circuit and an output of the interface circuit, and
a resistor coupled between the output of the interface circuit and a voltage reference source; and
a feedforward loop comprising the reference voltage source and an amplifier that has an input coupled to the input of the interface circuit and an output coupled to the reference voltage source,
wherein the capacitor and resistor are configured to operate as a low-pass filter that couples the reference voltage source to the output of the interface circuit.

2. The interface circuit of claim 1, wherein the reference voltage source is configured to sum the voltage at an output of the amplifier with a reference voltage to provide an output of the reference voltage source.

3. The interface circuit of claim 1, wherein a signal transmitted through the feedforward loop counteracts changes to a baseline voltage level at the output of the interface circuit attributable to a signal transmitted through the high-pass filter.

4. The interface circuit of claim 1, wherein the input of the interface circuit is configured to receive a high-frequency signal in excess of 100 MHz from a data communication link.

5. The interface circuit of claim 1, wherein the high-pass filter provides a low-impedance path from the input of the interface circuit to the output of the interface circuit for high-frequency signals.

6. The interface circuit of claim 1, wherein the feedforward loop provides a unitary gain path from the input of the interface circuit to the output of the interface circuit for direct current signals.

7. The interface circuit of claim 1, wherein the output of the interface circuit is coupled to an equalizer in a high-speed serializer-deserializer (SERDES) physical layer circuit.

8. A differential interface circuit, comprising:
a differential amplifier configured to receive an input of the differential interface circuit; and
a high-pass filter that includes:
a first capacitor coupled between a first complementary input of the interface circuit and a first complementary output of the interface circuit;
a first resistor coupled between the first complementary output of the interface circuit and a first complementary output of the differential amplifier, wherein the first capacitor and the first resistor are configured to operate as a low-pass filter that couples the first complementary output of the differential amplifier to the first complementary output of the interface circuit;
a second capacitor coupled between a second complementary input of the interface circuit and a second complementary output of the interface circuit; and
a second resistor coupled between the a second complementary output of the interface circuit and a second complementary output of the differential amplifier, wherein the second capacitor and the second resistor are configured to operate as a low-pass filter that couples the second complementary output of the differential amplifier to the second complementary output of the interface circuit.

9. The differential interface circuit of claim 8, wherein the differential amplifier is configured to sum an output voltage of the amplifier with a reference voltage to provide an output of the differential amplifier.

10. The differential interface circuit of claim 8, wherein a signal provided through the low-pass filter counteracts changes to a baseline voltage level at the output of the interface circuit attributable to a signal transmitted through the high-pass filter.

11. The differential interface circuit of claim 8, wherein the input of the differential interface circuit is configured to receive a high-frequency signal in excess of 100 MHz from a data communication link.

12. The differential interface circuit of claim 8, wherein the high-pass filter provides a low-impedance path from the input of the differential interface circuit to the output of the differential interface circuit for high-frequency signals.

13. The differential interface circuit of claim 8, wherein the differential amplifier provides a unitary gain path from the input of the interface circuit to the output of the interface circuit for direct current signals.

14. The differential interface circuit of claim 8, wherein the output of the differential interface circuit is coupled to an equalizer in a high-speed serializer-deserializer (SERDES) physical layer circuit.

15. A method for suppressing baseline wander, comprising:
filtering an input signal received by an interface circuit using a high-pass filter to obtain a filtered high-frequency signal;
filtering the input signal using a low-pass filter to obtain a filtered low-frequency signal;
adding the filtered low-frequency signal to a reference voltage using a summer; and
combining the filtered high-frequency signal with an output of the summer to provide an output of the interface circuit.

16. The method of claim 15, wherein combining the filtered high-frequency signal with an output of the summer counteracts changes to a baseline voltage level at the output of the interface circuit attributable to a signal transmitted through the high-pass filter.

17. The method of claim 15, wherein the reference voltage is configured to define a baseline voltage level at the output of the interface circuit.

18. The method of claim 15, wherein the input signal has frequency in excess of 100 MHz.

19. The method of claim 15, wherein the high-pass filter provides a low-impedance path for the input signal.

20. The method of claim 15, wherein the low-pass filter and the high-pass filter share one or more capacitors and one or more resistors.
